(19) United States
(12) Patent Application Publication
(10) Pub. No.: US 2012/0276745 A1
(43) Pub. Date: Nov. 1, 2012

(54) METHOD FOR FABRICATING HOLE PATTERN IN SEMICONDUCTOR DEVICE

(76) Inventors: Jin-Ki JUNG, Gyeonggi-do (KR); Jung-Hee Park, Gyeonggi-do (KR)

(21) Appl. No.: 13/331,064

(22) Filed: Dec. 20, 2011

(30) Foreign Application Priority Data
Apr. 29, 2011 (KR) 10-2011-0041042

(51) Int. Cl. H01L 21/311

(52) U.S. Cl. 438/703; 257/E21.249

(57) ABSTRACT

A method for fabricating a hole pattern in a semiconductor device includes forming a first organic layer over an etch layer, forming a first inorganic layer pattern over the first organic layer, etching the first organic layer using the first inorganic layer pattern as an etching barrier, forming a second organic layer over the first organic layer, forming a second inorganic layer pattern over the second organic layer, where the second inorganic layer pattern crosses the first inorganic pattern, etching the first and second organic layers using the second inorganic layer pattern as an etching barrier, and etching the etch layer using the etched first and second organic layers as an etch barrier to form a hole pattern.

### CROSS-REFERENCE TO RELATED APPLICATIONS

The present application claims priority of Korean Patent Application No. 10-2011-0041042, filed on Apr. 29, 2011, which is incorporated herein by reference in its entirety.

### BACKGROUND

1. Field

Exemplary embodiments of the present invention relate to semiconductor fabrication technology, and more particularly, to a method for fabricating a hole pattern in a semiconductor device.

2. Description of the Related Art

With the increase in integration degree of devices, the critical dimension (CD) of a pattern decreases. In sub-30 nm devices, for example, it is difficult to perform patterning using photoresist due to limitations in the resolution of exposure equipment.

Accordingly, a method of reducing the diameter of a contact hole through a reflow or RELACS (resolution enhancement lithography assisted by chemical shrink) process of photoresist has been proposed.

In the reflow process of photoresist, a contact hole pattern is formed using photoresist and subsequently cured at a glass transition temperature or more. At this time, the diameter of a contact hole decreases due to such a characteristic that the photoresist bulges during the curing process. In the RELACS process of photoresist, a contact hole pattern is formed using photoresist, a RELACS material is applied onto the photoresist pattern, and the photoresist and the RELACS material are reacted through a curing process to form a new layer, thereby reducing the diameter of a contact hole.

Here, while the reflow or RELACS process has an effect of reducing the diameter of the hole pattern, they do not reduce the pitch of the pattern. So far, it has been difficult to reduce the size of a semiconductor chip. For example, while extreme ultraviolet (EUV) exposure technology may be used, equipment is expensive and is still in the initial developing stages, where it is difficult to be commercialized.

Therefore, it is useful to have a method for fabricating a hole pattern in a semiconductor device, which is capable of overcoming physical limits of using a photoresist pattern and achieving high integration and forms a fine hole pattern.

### SUMMARY

An embodiment of the present invention is directed to a method for fabricating a hole pattern in a semiconductor device, which is capable of overcoming the limit of a photoresist pattern and forming a minute hole pattern.

Another embodiment of the present invention is directed to a method for fabricating a hole pattern in a semiconductor device, which is capable of simplifying a patterning process and securing a process margin.

In accordance with an embodiment of the present invention, a method for fabricating a hole pattern in a semiconductor device includes: forming a first organic layer over an etch layer; forming a first inorganic layer pattern over the first organic layer; etching the first organic layer using the first inorganic layer pattern as an etching barrier; forming a second organic layer over the first organic layer including the first inorganic layer pattern; forming a second inorganic layer pattern over the second organic layer, wherein the second inorganic layer pattern crosses the first inorganic pattern; etching the first and second organic layers using the second inorganic layer pattern as an etching barrier; and etching the etch layer using the etched first and second organic layers as an etch barrier to form a hole pattern.

In accordance with another embodiment of the present invention, a method for fabricating a hole pattern in a semiconductor device includes: forming a first organic layer pattern over an etch layer by etching the first organic layer; forming a first spacer pattern on sidewalls of the etched first organic layer; forming a second organic layer over the first organic layer and the first space pattern; patterning the second organic layer to form a second organic layer pattern that crosses the first organic layer pattern; forming a second spacer pattern on sidewalls of the patterned second organic layer; etching the second and first organic layers using the first and second spacer patterns as an etch barrier; and etching the etch layer using the etched first organic layer as an etch barrier, wherein the etched etch layer forms a hole pattern.

### BRIEF DESCRIPTION OF THE DRAWINGS

FIGS. 1A to 1F are cross-sectional views illustrating a method for fabricating a hole pattern in a semiconductor device in accordance with a first embodiment of the present invention.

FIGS. 2A to 2K are cross-sectional views illustrating a method for fabricating a hole pattern in a semiconductor device in accordance with a second embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

### First Embodiment

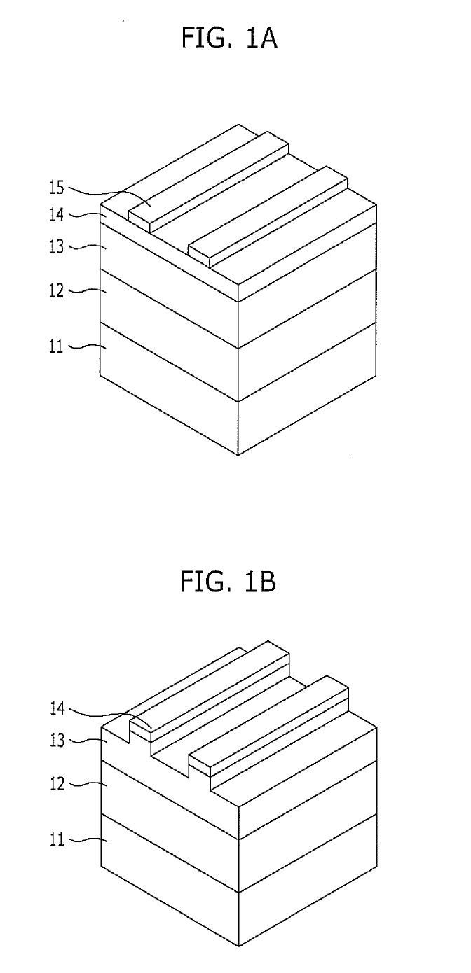

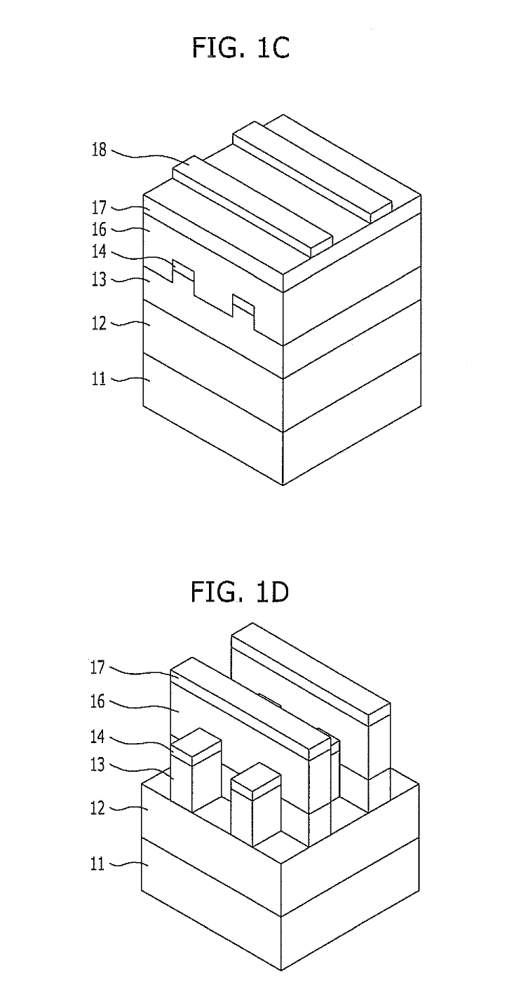

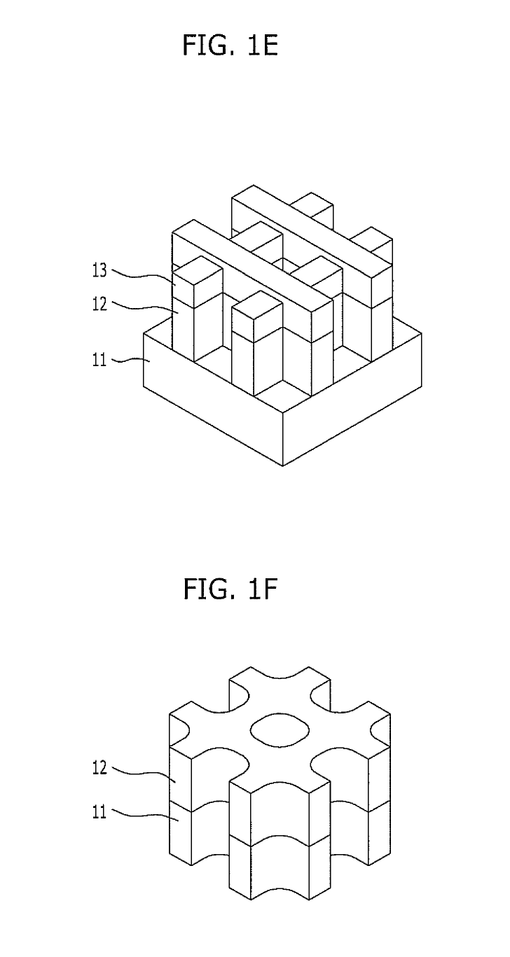

FIGS. 1A to 1F are cross-sectional views illustrating a method for fabricating a hole pattern in a semiconductor device in accordance with a first embodiment of the present invention.

Referring to FIG. 1A, a hard mask layer 12, a first organic layer 13, and a first inorganic layer 14 are stacked over a layer 11 which is to be etched (hereinafter, referred to as an etch layer 11). The etch layer 11 may include a mold layer for forming a storage node and may be formed of oxide or polysilicon.

The hard mask layer 12 serves as an etch barrier for etching the etch layer 11. When the etch layer 11 is formed of oxide, the hard mask layer 12 may be formed of polysilicon, and when the etch layer 11 is formed of polysilicon, the hard mask layer 12 may be formed of oxide.

The first organic layer 13 is formed of carbon and may include an amorphous carbon layer. The first inorganic layer 14 serves as an etch barrier of the first organic layer 13 and serves to prevent reflection when a photoresist pattern is formed. The first inorganic layer 14 includes silicon oxynitride.

A first photoresist pattern 15 is formed over the first inorganic layer 14. Before the first photoresist pattern 15 is formed, a reflection prevention layer may be additionally formed over the first inorganic layer 14. The first photoresist pattern 15 is formed as a line extending in a first direction.

Referring to FIG. 1B, the first inorganic layer 14 is etched using the first photoresist pattern 15 as an etch barrier.

The first organic layer 13 is partially etched to a desired thickness. In this embodiment of the present invention, it has been described that the first organic layer 13 is partially etched to a desired thickness. However, the first organic layer 13 may be completely etched until the hard mask layer 12 is exposed. When the etching of the first organic layer 13, the first photoresist pattern 15 is also completely removed. The first organic layer 13 is etched by dry etching, and plasma etching may be performed using gas including oxygen.

Referring to FIG. 1C, a second organic layer 16 is formed over the first inorganic layer 14 and the first organic layer 13. The second organic layer 16 is formed of carbon and includes a spin on carbon (SOC) layer.

A second inorganic layer 17 is formed over the second organic layer 16. The second inorganic layer 17 serves as an etch barrier of the second organic layer 16, and serves to prevent reflection when a photoresist pattern is formed. The second inorganic layer 17 includes silicon oxynitride.

A second photoresist pattern 18 is formed over the second inorganic layer 17. Before the second photoresist pattern 18 is formed, a reflection prevention layer may be additionally formed over the second inorganic layer 17. The second photoresist pattern 18 is formed as a line extending in a second direction perpendicular to the first direction.

Referring to FIG. 1D, the second inorganic layer 17 is etched using the second photoresist pattern 18 as an etch barrier.

Subsequently, the second organic layer 16 is etched using the second inorganic layer 17 as an etch barrier. The second organic layer 16 is etched as a line extending in the second direction by the second inorganic layer 17. After the etching of the second organic layer 16, the first organic layer 13 positioned under the second organic layer 16 and exposed by the etching is continuously etched.

More specifically, after the etching of the second organic layer 16, the first inorganic layer 14 formed as a line extending in the first direction is used as an etch pattern for etching the first organic layer 13. Therefore, the first organic layer 13 is etched in such a manner that a mesh-type hole pattern is opened by the first inorganic layer 14 extended in the first direction and the second inorganic layer 17 extended in the second direction perpendicular to the first direction.

The second organic layer 16 and the first organic layer 13 are etched by dry etching, and plasma etching may be performed using gas including oxygen.

When the second organic layer 16 and the first organic layer 13 are being etched, the second photoresist pattern 18 is also completely removed.

Referring to FIG. 1E, the hard mask layer 12 is etched using the second organic layer 16 and the first organic layer 13 as an etch barrier to form a mesh-type hard mask pattern 12.

Referring to FIG. 1F, the etch layer 11 is etched using the hard mask pattern 12 as an etch barrier to form a hole pattern. The hard mask pattern 12 is formed in a mesh type having a rectangular shape. However, during the etching of the lower layer, the corners of the mask pattern 12 are rounded due to the characteristic of the etching, and thus a circular hole pattern is formed.

Before the etch layer 11 is etched, the organic layer over the hard mask pattern 12 may be previously removed through an oxygen stripping process.

As the first and second organic layers 13 and 16 are simultaneously etched to form the mesh-type hole pattern and the number of stacked layers is minimized/reduced, the number of processes may be reduced to secure a process margin. Furthermore, as the number of stacked layers is minimized/reduced, the occurrence of defects which may be caused by several deposition and etching processes may also be prevented. Therefore, the hole pattern may be reliably formed.

### Second Embodiment

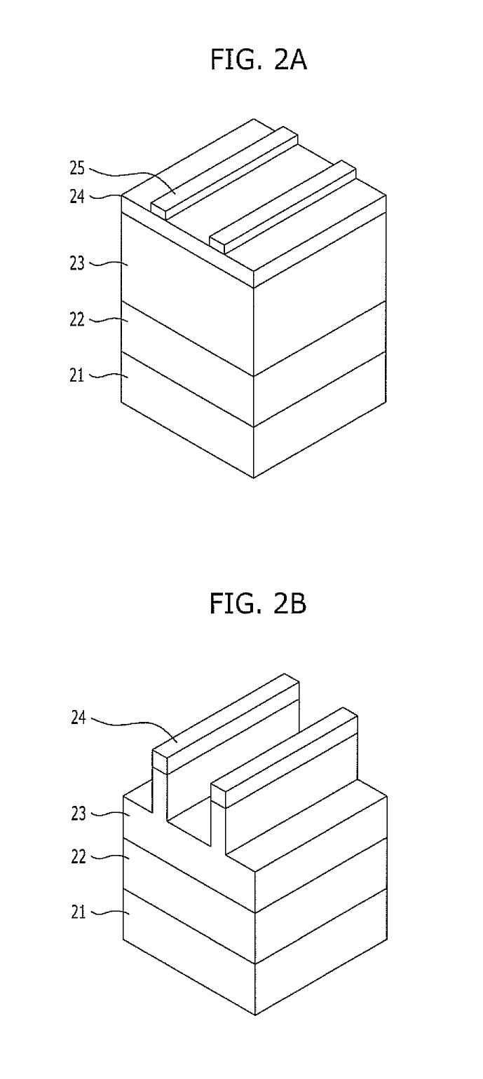

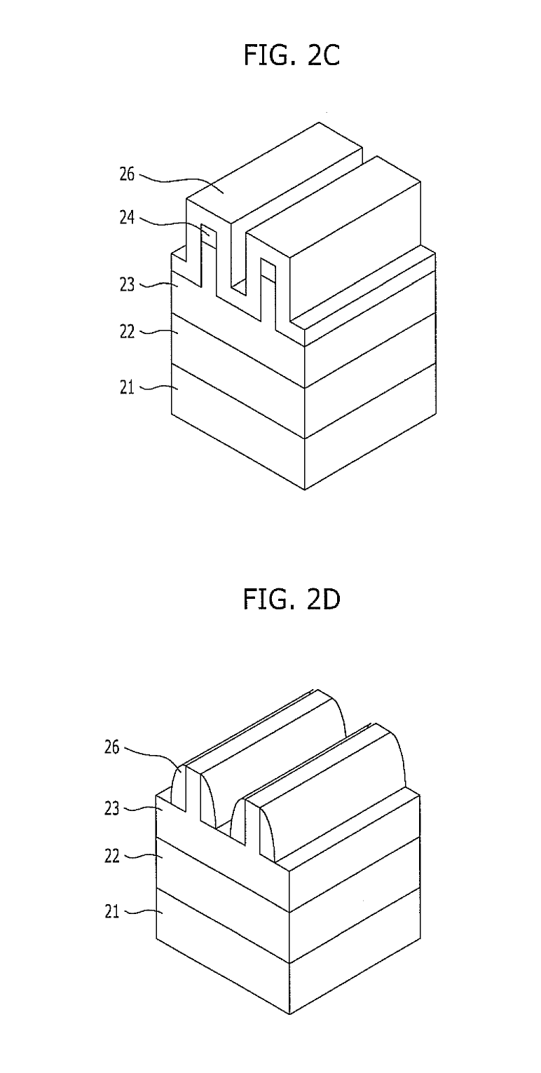

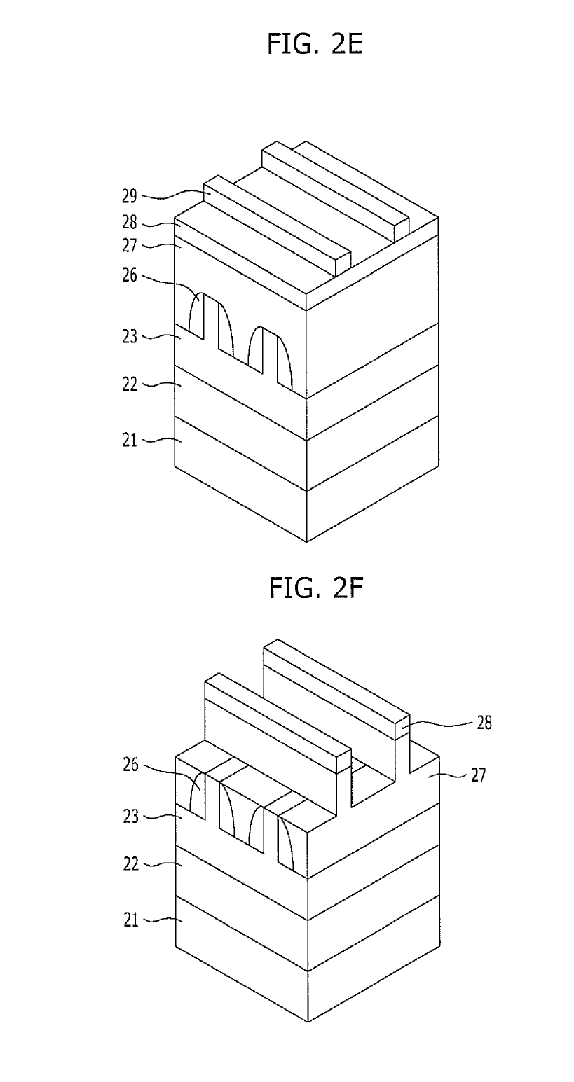

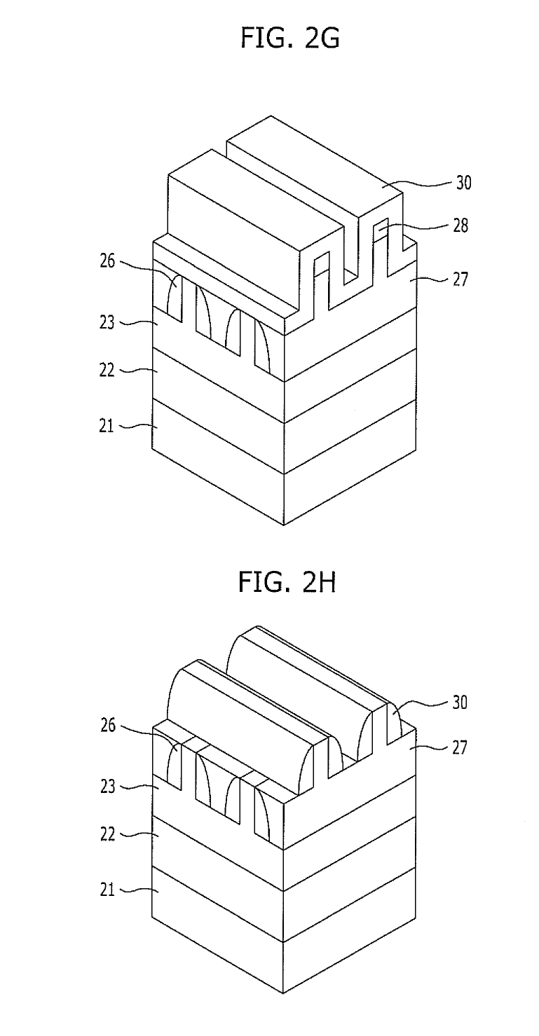

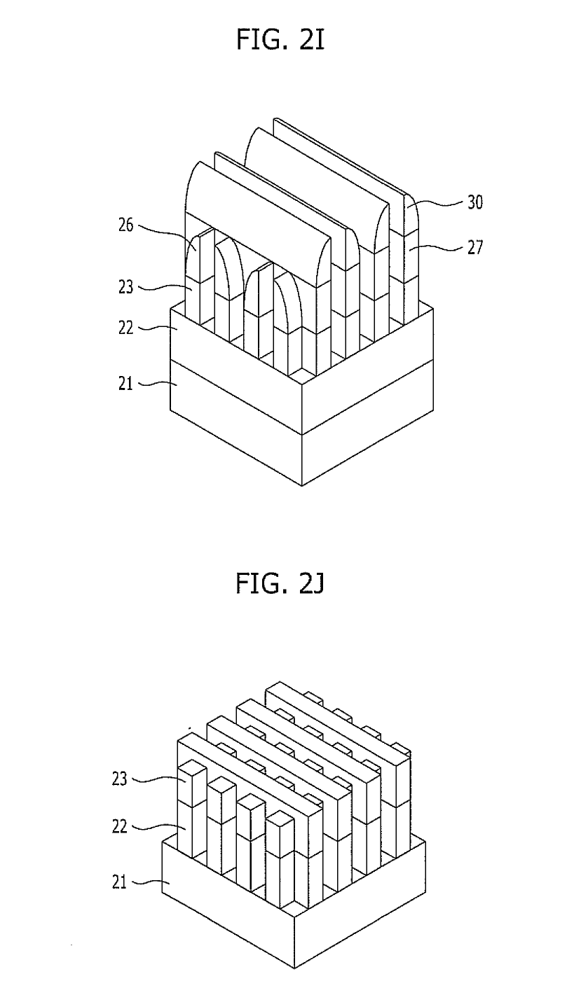

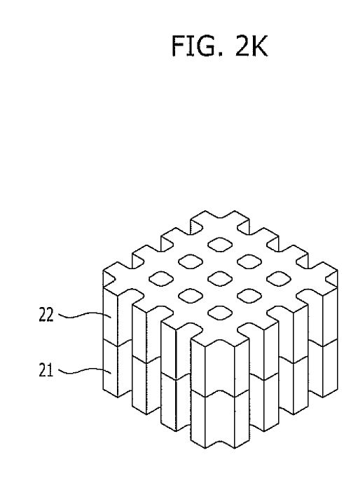

FIGS. 2A to 2K are cross-sectional views illustrating a method for fabricating a hole pattern in a semiconductor device in accordance with a second embodiment of the present invention.

Referring to FIG. 2A, a hard mask layer 22, a first organic layer 23, and a first inorganic layer 24 are stacked over an etch layer 21. The etch layer 21 may include a mold layer for forming a storage node and may be formed of oxide or polysilicon.

The hard mask layer 22 serves as an etch barrier for etching the etch layer 21. When the etch layer 21 is formed of oxide, the hard mask layer 22 may be formed of polysilicon, and when the etch layer 21 is formed of polysilicon, the hard mask layer 22 may be formed of oxide.

The first organic layer 23 is formed of carbon and may include an amorphous carbon layer. The first inorganic layer 24 serves as an etch barrier of the first organic layer 23 and serves to prevent reflection when a photoresist pattern is formed. The first inorganic layer 24 includes silicon oxynitride.

A first photoresist pattern 25 is formed over the first inorganic layer 24. Before the first photoresist pattern 25 is formed, a reflection prevention layer may be additionally formed over the first inorganic layer 24. The first photoresist pattern 25 is formed as a line extending in a first direction. Here, the formation of a subsequent spacer pattern may be controlled to take in to consideration a distance between the first photoresist patterns 25.

Referring to FIG. 2B, the first inorganic layer 24 is etched using the first photoresist pattern 25 as an etch barrier.

Subsequently, the first organic layer 23 is partially etched to a desired thickness. After the etching of the first organic layer 23, the first photoresist pattern 25 is completely removed. The first organic layer 23 is etched by dry etching, and plasma etching may be performed using gas including oxygen. At this time, the first organic layer 23 may be etched to such a thickness as to serve as a sacrifice pattern for forming a subsequent spacer pattern.

Referring to FIG. 2C, a first spacer layer 26 is formed along the step portions of the entire structure including the first organic layer 23.

The first spacer layer 26 is formed of a material (for example, an insulation layer) having an etching selectivity with respect to an organic layer. The insulation layer may any reasonably suitable insulation layering including nitride and oxide. Furthermore, the first spacer layer 26 may be formed at such a temperature that the pattern of the first organic layer 23 is not distorted. For example, the first spacer layer 26 is formed at a temperature of at least 600° C. or less.

Referring to FIG. 2D, the first spacer layer 26 is etched to form a first spacer pattern 26 remaining on the sidewalls of the partially-etched first organic layer 23. The etching is controlled in such a manner that the first inorganic layer 24 over the first organic layer 23 is completely removed to expose the first organic layer 23 at a region between the first spacer patterns 26 after the formation of the first spacer pattern 26.

Therefore, the first spacer pattern 26 is formed on the sidewalls of the first organic layer 23, which was partially-etched previously as a line extending in the first direction, and the other area of the first organic layer 23 is exposed.

Referring to FIG. 2E, a second organic layer 27 is formed over the first organic layer 23 including the first spacer pattern 26. The second organic layer 27 is formed of carbon, and includes an SOC layer. As the second organic layer 27 is formed of an SOC layer, the space between the first spacer patterns 26 is filled. Subsequently, planarization is performed.

A second inorganic layer 28 is formed over the second organic layer 27. The second inorganic layer 28 serves as an etch barrier of the second organic layer 27 and serves to prevent reflection when a photoresist pattern is formed. The second inorganic layer includes silicon oxynitride.

A second photoresist pattern 29 is formed over the second inorganic layer 28. Before the second photoresist pattern 29 is formed, a reflection prevention layer may be additionally formed over the second inorganic layer 28. The second photoresist pattern 29 is formed as a line extending in a second direction perpendicular to the first direction. The distance between the second photoresist patterns 29 may be controlled by taking into consideration the subsequent formation of a spacer pattern.

Referring to FIG. 2F, the second inorganic 28 is etched using the second photoresist pattern 29 as an etch barrier.

The second organic layer 27 is partially etched using the second inorganic layer 28 as an etch barrier. At this time, the second organic layer 27 is etched to such a target thickness as to expose the first spacer pattern 26.

When the etching of the second organic layer 27 is completed, the second photoresist pattern 29 is also completely removed.

Referring to FIG. 2G, a second spacer layer 30 is formed along the step portions of the entire structure including the second inorganic layer 28. The second spacer layer 30 is formed of a material having an etching selectivity with respect to the first and second organic layers 23 and 27, for example, an insulation layer. The insulation layer may include any reasonably suitable insulation layer including nitride and oxide. Furthermore, the second spacer layer 30 may be formed at such a temperature that the pattern of the second organic layer 27 is not distorted. For example, the second spacer layer 30 is formed at a temperature of at least 600° C. or less.

Referring to FIG. 2H, the second spacer layer 30 is partially etched to form a second spacer pattern 30 remaining on the sidewalls of the partially-etched second organic layer 27. The etching is controlled in such a manner that the second inorganic layer 28 over the second organic layer 27 is also completely removed to expose the second organic layer 27 between the second spacer patterns 30 when the formation of the second spacer pattern 30 is completed.

Accordingly, the second spacer pattern 30 is formed on the sidewalls of the second organic layer 27 which is partially etched as a line extending in the second direction, and the first spacer pattern 26 and the first organic layer 23 formed as a line extending in the first direction as well as the second organic layer 27 are exposed between the second spacer patterns 30. That is, the first and second organic layers 23 and 27 are exposed between the first spacer patterns 26 and between the second spacer patters 30, respectively.

Referring to FIG. 2I, the first and second organic layers 23 and 27 are etched using the first and second spacer patterns 26 and 30 as an etch barrier. Since the first and second spacer patterns 26 and 30 have an etching selectivity with respect to the first and second organic layers 23 and 27, the organic layer between the spacer patterns may be selectively etched without etching away the spacer patterns. In particular, the first organic layer 23 is etched in such a manner that a mesh-type hole pattern is opened by the first and second spacer patterns 26 and 30.

The second organic layer 27 and the first organic layer 23 are etched by dry etching, and plasma etching may be performed using gas including oxygen.

Referring to FIG. 2J, the first and second spacer patterns 26 and 30 are removed. As the first and spacer patterns 26 and 30 having an asymmetrical structure are previously removed before the lower layers are etched, the critical dimension (CD) uniformity of the hole pattern may be removed.

The hard mask layer 22 is etched using the mesh-type first organic layer 23 as an etch barrier to form a hard mask pattern 22 in a mesh type.

Referring to FIG. 2K, the etch layer 21 is etched using the hard mask pattern 22 as an etch barrier to form a hole pattern. The hard mask pattern 22 is formed in a mesh type having a rectangular shape. During the etching of the lower layer, however, the corners of the hard mask pattern are rounded due to an etching characteristic. Thus, a circular hole pattern is formed.

Before the etch layer 21 is etched, the organic layer over the hard mask pattern 22 is previously removed by an oxygen stripping process.

As the first and second organic layers 23 and 27 are partially etched to form the first and second spacer patterns 26 and 30, a fine hole pattern may be formed. Furthermore, as the first and second organic layers 23 and 27 are simultaneously etched using the first and second spacer patterns 26 and 30 as an etch barrier to form the mesh-type hole pattern, the number of stacked layers is minimized/reduced, and thus, the number of processes may be reduced to secure a process margin. Furthermore, as the number of stacked layers is minimized/reduced, the occurrence of defects which may be caused by several deposition and etching processes may also be prevented. Therefore, the hole pattern may be stably formed.

In accordance with the embodiments of the present invention, the line-type mask patterns perpendicular to each other are used to form the hole pattern in a mesh type and overcomes physical limits in the resolution of the photoresist pattern.

Furthermore, as an organic layer is applied as the hard mask pattern for forming the hole pattern and the two organic layers are simultaneously etched, the number of stacked layers may be minimized/reduced. Therefore, the number of processes may be reduced to secure a process margin.

Furthermore, as the number of stacked layers is minimized/reduced, the occurrence of defects which may be caused by several deposition and etching processes may also be prevented. Therefore, the hole pattern may be reliably formed.

Furthermore, after the organic layer is partially etched, the spacer pattern is formed on the sidewall of the organic layer and used as an etch barrier. Therefore, a fine hole pattern may be formed.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a hole pattern in a semiconductor device, comprising:
forming a first organic layer over an etch layer;
forming a first inorganic layer pattern over the first organic layer;
etching the first organic layer using the first inorganic layer pattern as an etching barrier;
forming a second organic layer over the first organic layer including the first inorganic layer pattern;
forming a second inorganic layer pattern over the second organic layer, wherein the second inorganic layer pattern crosses the first inorganic pattern;
etching the first and second organic layers using the second inorganic layer pattern as an etching barrier; and
etching the etch layer using the etched first and second organic layers as an etch barrier to form a hole pattern.

2. The method of claim 1, wherein the first and second organic layers comprises carbon.

3. The method of claim 1, wherein the first organic layer comprises amorphous carbon.

4. The method of claim 1, wherein the second organic layer comprises a spin on carbon (SOC) layer.

5. The method of claim 1, wherein the first and second inorganic layers each comprise silicon oxynitride.

6. The method of claim 1, wherein the etch layer comprises oxide and the hard mask layer comprises polysilicon.

7. The method of claim 1, wherein the etch layer comprises polysilicon and the hard mask layer comprises oxide.

8. A method for fabricating a hole pattern in a semiconductor device, comprising:
forming a first organic layer pattern over an etch layer by etching the first organic layer;
forming a first spacer pattern on sidewalls of the etched first organic layer;
forming a second organic layer over the first organic layer and the first space pattern;
patterning the second organic layer to form a second organic layer pattern that crosses the first organic layer pattern;
forming a second spacer pattern on sidewalls of the patterned second organic layer;
etching the second and first organic layers using the first and second spacer patterns as an etch barrier; and
etching the etch layer using the etched first organic layer as an etch barrier, wherein the etched etch layer forms a hole pattern.

9. The method of claim 8, wherein the forming of the first organic layer comprises:
forming a first organic layer over the etch layer;
forming a first inorganic layer over the first organic layer;
forming a photoresist pattern over the first inorganic layer;
etching the first inorganic layer using the photoresist pattern as an etch barrier; and
etching the first organic layer using the first inorganic layer as an etch barrier.

10. The method of claim 8, wherein the forming of the first spacer pattern comprises:
forming a first spacer layer along step portions of a structure including the first organic layer after etching the first organic layer; and
etching the first spacer layer to form a first spacer pattern remaining on the sidewalls of the etched first organic layer.

11. The method of claim 8, wherein the patterning of the second organic layer comprises:
forming a second inorganic layer over the second organic layer;
forming a photoresist pattern over the second inorganic layer;
etching the second inorganic layer using the photoresist pattern as an etch barrier; and
etching the second organic layer using the second inorganic layer as an etch barrier such that the first spacer pattern is exposed.

12. The method of claim 8, wherein the first and second organic layers comprise carbon.

13. The method of claim 8, wherein the first organic layer comprises amorphous carbon.

14. The method of claim 8, wherein the second organic layer comprises a spin on carbon (SOC) layer.

15. The method of claim 8, wherein the first and second inorganic layers comprise silicon oxynitride.

16. The method of claim 8, wherein the first and second spacer patterns comprise oxide or nitride.

17. The method of claim 8, wherein the etch layer comprises oxide and the hard mask layer comprises polysilicon.

18. The method of claim 8, wherein the etch layer comprises polysilicon and the hard mask layer comprises oxide.
